(19) United States
(12) Patent Application Publication
(10) Pub. No.: US 2026/0189231 A1
(43) Pub. Date: Jul. 2, 2026

(54) GATE DRIVER TO CONTROL CURRENT THROUGH A TRANSISTOR TO A CAPACITOR OR CAPACITIVE LOAD

(71) Applicant: TEXAS INSTRUMENTS INCORPORATED, Dallas, TX (US)

(72) Inventors: Xiaochun Zhao, Allen, TX (US); Eung Jung Kim, Allen, TX (US); Arjun Pankaj, Dallas, TX (US)

(21) Appl. No.: 19/002,922

(22) Filed: Dec. 27, 2024

(51) Int. Cl. H03K 17/687; G05F 3/26

(52) U.S. Cl. CPC H03K 17/687; G05F 3/262

(57) ABSTRACT

An apparatus includes a current source circuit having a first control input, a second control input, and an output. The current source circuit is configured to produce a current at the output at a first current level based on a first signal at the first control input being at a first logic level and at a second current level based on the first signal at the first control input being at a second logic level. The current source circuit is configured to produce the current at the output at a third current level based on a second signal at the second control input. A capacitor has a first terminal coupled to the output of the current source circuit and has a second terminal coupled to a voltage supply terminal. A buffer has a buffer input coupled to the first terminal and has a buffer output.

### BACKGROUND

In many systems, power to a load is provided through a solid-state switch (e.g., a transistor). A control circuit turns the transistor on to allow current from a power source to flow to the load to thereby power the load. Some loads are capacitive in nature or have a capacitor coupled in parallel with the load. With the transistor on, the capacitor charges. The charged capacitor allows the load to continue to operate in the face of a momentary loss of current from the power source.

### SUMMARY

In one example, an apparatus includes a current source circuit having a first control input, a second control input, and an output. The current source circuit is configured to produce a current at the output at a first current level based on a first signal at the first control input being at a first logic level and at a second current level based on the first signal at the first control input being at a second logic level. The current source circuit is configured to produce the current at the output at a third current level based on a second signal at the second control input. A capacitor has a first terminal coupled to the output of the current source circuit and has a second terminal coupled to a voltage supply terminal. A buffer has a buffer input coupled to the first terminal and has a buffer output.

In another example, an apparatus includes a transistor having a control terminal. The apparatus also includes a driver including a configurable current source circuit, the configurable current source circuit has control inputs. The driver has a driver output coupled to the control terminal. The driver is configured to generate a voltage at the control terminal that changes at multiple rates based on control signals at the control inputs of the configurable current source circuit.

In yet another example, a driver includes a current source circuit having a first control input, a second control input, and an output. A capacitor has a first terminal coupled to the output of the current source circuit and has a second terminal coupled to a voltage supply terminal. A buffer has a buffer input coupled to the first terminal and has a buffer output. A first comparator has first and second comparator inputs and an output. The first comparator input is coupled to a first terminal of the driver. The second comparator input is configured to receive a first reference signal. The output of the first comparator is coupled to the first control input of the current source circuit. A second comparator has third and fourth comparator inputs and an output. The third comparator input is coupled to a second terminal of the driver. The fourth comparator input is configured to receive a second reference signal. The output of the second comparator is coupled to the second control input of the current source circuit.

### BRIEF DESCRIPTION OF THE DRAWINGS

FIG. 1 is a schematic diagram of a system which includes a gate driver and a transistor, in an example.

FIG. 2 includes waveforms illustrating the operation of the gate driver of FIG. 1.

FIG. 3 is a schematic diagram providing an example of additional detail for the gate driver of FIG. 1.

FIG. 4 is a schematic diagram of a buffer included within the gate driver of FIGS. 1 and 2, in an example.

FIG. 5 is a schematic diagram providing yet additional detail for the gate driver of FIGS. 1 and 2, in an example.

### DETAILED DESCRIPTION

The same reference numbers or other reference designators are used in the drawings to designate the same or similar (either by function and/or structure) features.

The examples described herein include a capacitor coupled in parallel with a load. However, the principles described herein also pertain to a load that is capacitive in nature. In some examples, the power source for the load is a battery, such as the battery in an automobile. In other examples, the power source for the load is from a power converter.

As the transistor noted above is turned on, the capacitor begins to charge. Until the voltage across the capacitor is at or above the minimum supply voltage rating for the load, the load remains in an off state. The current to the capacitor is proportional to the product of the capacitance of the capacitor and the rate of change of voltage across the capacitor, in other words, I=C*dv/dt, where I is the current to the capacitor, C is the capacitance of the capacitor, and dv/dt is rate of change of voltage across the capacitor. In the example of an automobile, the power source for the load is the automobile's battery, which may be a 12V battery. Accordingly, the change in voltage to the load is 12V. Given the relatively short time that a transistor takes to turn on, the value of dv/dt is substantially large. Further, the capacitance C may also be substantially large, for example, on the order of milli-Farads. As a result of large values of C and dv/dt, the current that flows through the transistor to charge the capacitor can be substantially high. The current that flows through the transistor flows through the transistor's drain-to-source resistance, thereby causing the transistor to dissipate power. Power dissipated in a transistor causes the transistor's temperature to increase. The level of current I through the transistor as the capacitor charges can be high enough to cause the transistor to overheat potentially damaging the transistor. Some control circuits that turn the transistor on and off may respond to a thermal problem with the transistor by turning the transistor off. However, turning the transistor off may prevent the capacitor from fully charging and may prevent the load from turning and operating.

The examples described herein are directed to a gate driver circuit that controls turning on the transistor to provide to charge a load's capacitor in such a way that avoids the current from through the transistor from being so high as to cause a thermal shutdown event. The described gate driver allows the current through the transistor to be high enough so as to cause the transistor to turn on relatively quickly. In some examples, the gate driver implements a multi-phased turn-on process for the transistor whereby the gate voltage for the transistor is controlled by the gate driver to change at different rates as the capacitor charges.

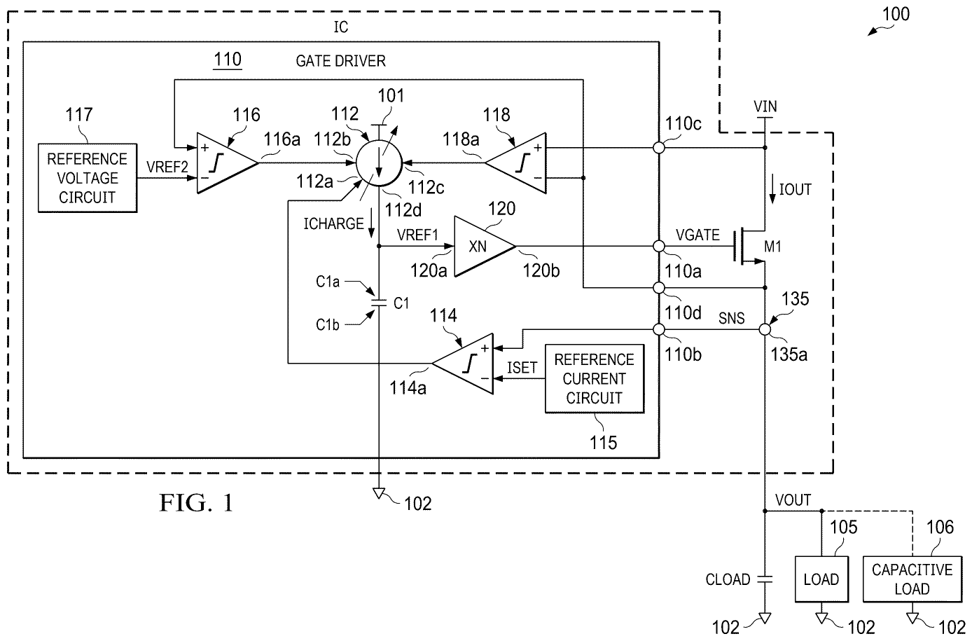

FIG. 1 is a schematic diagram of a system 100 that includes a gate driver 110, a transistor M1, a capacitor CLOAD, and a load 105. Capacitor CLOAD is coupled in parallel with load 105 between transistor M1 (e.g., between a terminal such as a source) and a voltage supply terminal (e.g., ground) 102. The voltage across capacitor CLOAD is voltage VOUT. System 100 may include multiple loads 105 and each such load 105 may be coupled in parallel with a capacitor CLOAD. In other examples (as indicated by the dashed lines), system 100 includes a capacitive load 106 instead of a load 105 separate from, but in parallel with, capacitor CLOAD. In yet other examples, system 100 includes a combination of a capacitor CLOAD/load 105 and a capacitive load 106.

Gate driver 110 turns transistor M1 on and off. In response to transistor M1 being on, current IOUT flows from a supply voltage terminal 101 (VIN), through transistor M1, and to capacitor CLOAD and load 105. In some applications, system 100 is part of an automobile, and voltage VIN is the voltage from the automobile's battery (e.g., 12V). In automobile applications, load 105 is a subsystem within the automobile. Examples of loads 105 in an automobile include an infotainment system, an antilock brake system, etc.

In the example of FIG. 1, gate driver 110 has a driver output 110a, which is coupled to the gate of transistor M1. Driver 110 also has terminals 110b, 110c, and 110d. Gate driver 110 includes a current source circuit 112, a capacitor C1, comparators 114, 116, and 118, a buffer 120, a reference current circuit 115, and a reference voltage circuit 117. Current source circuit 112 has control inputs 112a, 112b, and 112c, and an output 112d. Buffer 120 has a buffer input 120a and a buffer output 120b. Capacitor C1 has terminals C1a and C1b. Terminal C1a of capacitor C1 is coupled to output 112d of current source circuit 112 and to buffer input 120a. Terminal C1b of capacitor C1 is coupled to voltage supply terminal 102. Buffer output 120b is coupled to driver output 110a and, accordingly, to the gate of transistor M1. Buffer 120 generates an output voltage VGATE at its output 120b.

Current ICHARGE from current source circuit 112 charges capacitor C1 to a voltage VREF1, which is the input voltage to buffer 120. Buffer 120 implements a gain of ‘n’ (e.g., n is greater than 1) by which the buffer's output voltage VGATE is n-times larger than its input voltage VREF1. In one example, n is 9, but in other examples, n is other than 9. The rate of change of voltage VREF1 (dVREF1/dt) is proportional to the magnitude of current ICHARGE from current source circuit 112 and the capacitance of capacitor C1, for example, dVREF1/dt=ICHARGE/C1. Accordingly, by controlling the magnitude of current ICHARGE, current source circuit 112 controls the rate of change of voltage VREF1. Buffer 120 produces the gate voltage VGATE for transistor M1 that is n-times larger than voltage VREF1. The rate of change of gate voltage VGATE is proportional to the rate of change of voltage VREF1. For example, dVGATE/dt is n-times larger than dVREF1/dt. Accordingly, current source circuit 112 generates a current ICHARGE that controls the rate of change of gate voltage VGATE for transistor M1.

Current source circuit 112 generates current ICHARGE at any of multiple current levels. The current level of current ICHARGE is based on the signals provided at control inputs 112a, 112b, and 112c. Comparator 114 has a positive (+) input, a negative input (−), and an output 114a. The positive input of comparator 114 is coupled to driver terminal 110b. A current sense circuit 135 is coupled to transistor M1, for example, to the source of transistor M1. Current sense circuit 135 may include a sense resistor (e.g., 20 milli-ohms), whose voltage is proportional to the current IOUT through the sense resistor. In another example, current sense circuit 135 includes a transistor substantially smaller than transistor M1 and coupled in parallel with transistor M1. Current sense circuit 135 produces a current sense signal SNS which is proportional to the current IOUT through transistor M1. Output 135a of current sense circuit 135 is coupled to driver terminal 110b and to the positive input of comparator 114. Reference current circuit 115 is coupled to the negative input of comparator 114 and produces a current ISET. Comparator 114 is a current comparator which compares a current sense signal from the output 135a of current sense circuit 135 to reference current ISET. Current sense circuit 135 has a sense output 135a which is coupled to the positive input of comparator 114. The output 114a of comparator 114 is coupled to control input 112a of current source circuit 112. In the example of FIG. 1, if the sense signal SNS is smaller than the reference current ISET, comparator 114 generates its output signal to be a logic low (‘0’). Otherwise, if the sense signal SNS is larger than the reference current ISET, comparator 114 generates its output signal to be a logic high (‘1’).

Comparator 116 has positive and negative inputs and an output 116a. The positive input of comparator 116 is coupled to a terminal 110d of driver 110 and to the source of transistor M1. The negative input of comparator 116 is coupled to reference voltage circuit 117 and receives a reference voltage VREF2 generated by reference voltage circuit 117. Voltage VREF2 may correspond to a minimum voltage needed for load 105 to correctly operate. In one example, reference voltage VREF2 is 3V. The output 116a of comparator 116 is coupled to control input 112b of current source circuit 112. Comparator 116 is a voltage comparator which compares VOUT to reference voltage VREF2. If VOUT is smaller than VREF2, comparator 116 produces an output signal to control input 112b at a logic low level; otherwise, if VOUT is larger than VREF2, comparator 116 produces an output signal to control input 112b at a logic high level.

Comparator 118 has positive and negative inputs and an output 118a. The positive input of comparator 118 is coupled to a terminal 110c of driver 110 and to the drain of transistor M1. The negative input of comparator 118 is coupled to terminal 110d of driver 110 and to the source of transistor M1. The output 118a of comparator 118 is coupled to control input 112c of current source circuit 112. Comparator 118 determines whether input voltage VIN is more than a threshold voltage implemented within comparator 118 larger than output voltage VOUT. If VIN is more than the reference voltage of comparator 118 larger than VOUT, comparator 118 produces an output signal to control input 112c at a logic high level; otherwise, if VOUT is within the reference voltage of VIN, comparator 118 produces an output signal to control input 112b at a logic low level. In other words, comparator 118 determines when capacitor CLOAD has charged to the point at which VOUT is fairly close to VIN (e.g., within the threshold voltage of comparator 118).

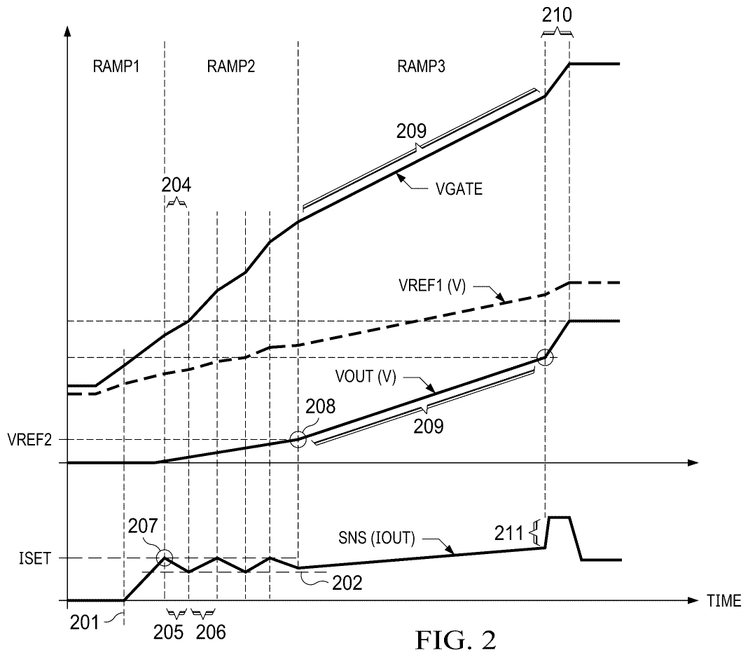

FIG. 2 includes waveforms of voltages VREF1, VGATE, and VOUT and current sense signal SNS (which is a proxy for current IOUT) during multiple phases denoted as RAMP1, RAMP2, and RAMP3. Referring to FIGS. 1 and 2, during operation to turn on transistor M1 and begin to charge capacitor C1, initially current source circuit 112 generates current ICHARGE during the RAMP1 phase at a level that causes capacitor C1 to charge fairly rapidly as indicated by the slope of voltage VREF1 during the RAMP1 phase. VGATE is n-times larger than VREF1. At time point 201, VGATE reaches the threshold voltage of transistor M1, and transistor M1 responds by turning on. With transistor M1, current IOUT begins to flow through transistor M1 and capacitor CLOAD begins to charge. The voltage across capacitor CLOAD is VOUT and, accordingly, voltage VOUT begins to increase as well. As noted above, the voltage VOUT is the voltage on the source of transistor M1. During the remainder of the phases RAMP1, RAMP2, and RAMP3, current IOUT continues to flow to capacitor CLOAD, and, accordingly, the voltage VOUT continues to increase.

Comparator 114 compares sense signal SNS to ISET, as described above. Comparator 114 implements hysteresis such that the output 114a of comparator is forced to a logic high level when SNS is above ISET and is forced back to a logic low level when SNS falls below level 202. The difference between ISET and level 202 is the hysteresis of comparator 214. In response to SNS reaching ISET at point 207, phase RAMP2 begins, comparator 114 generates a logic high signal at its output 114a, and current source circuit 112 responds by decreasing the level of current ICHARGE. With a lower level of current ICHARGE, the rate of change of voltage VREF1 decreases and, similarly, the rate of change of voltage VGATE also decreases as illustrated at 204. With gate voltage for transistor M1 continuing to increase but at a lower rate while the source voltage (VOUT) continues to increase, the gate-to-source voltage (Vgs) of transistor decreases which, in turn, causes IOUT and sense signal SNS to decrease as illustrated at 205.

In response to sense signal SNS reaching the lower level 202 of the hysteresis of comparator 114, current source circuit 212 responds by increasing the level of current ICHARGE to a level that may be less than the level implemented during the phase RAMP1 but more than the level during 204. At the higher level of current ICHARGE, the rate of change of voltage VREF1, and thus VGATE, increases as indicated at 205. The Vgs of transistor M1 increases in response and, accordingly, the output current IOUT and sense signal SNS also increases as indicated at 206. During phase RAMP2, current source circuit 212 causes current ICHARGE to toggle between two relatively low levels based on the comparison between sense signal SNS and ISET and the lower level 202 of the comparator's hysteresis. This process maintains the charge current IOUT to capacitor CLOAD at a low enough level to avoid a thermal event as described above.

Phase RAMP2 ends and phase RAMP3 begins when voltage VOUT reaches voltage VREF2, which is identified by point 208. Comparator 116 compares VOUT to voltage VREF2 and generates a logic high signal to control input 112b of current source circuit 112 when VOUT reaches VREF2. In response to a logic high assertion at control input 112b, current source circuit 112, increases the level of current ICHARGE to a level that is higher than the levels of current ICHARGE during phase RAMP2. Because of the higher level of current ICHARGE, voltage VREF1 increases at an even higher rate during phase RAMP3 than was the case during phase RAMP2. Voltage VGATE also increases at a higher rate during phase RAMP3 (reference numeral 209) than during phase RAMP2. The gate voltage of transistor M1 can be increased at a relatively fast rate during phase RAMP3 because the transistor's source voltage (VOUT) is also increasing. As a result, the Vgs of transistor M1 is not so high during phase RAMP3 as to be at risk for current IOUT being high enough to cause transistor M1 to become too hot. The reduced drain-to-source voltage (Vds) of transistor M1 during the phase RAMP3 is smaller than during phases RAMP1 and RAMP2 thereby also reducing heat generated by transistor M1.

Phase RAMP3 ends when voltage VOUT is near the input voltage VIN, which means that the Vds of transistor M1 is fairly low and, accordingly, the power dissipated in transistor M1 is low enough so as not to overheat the transistor. Comparator 118 determines when VOUT is within a threshold level of VIN. In one example, the threshold level is 2V, meaning that comparator 118 generates a logic high at its output 118a when VOUT is within 2V of VIN. In response to assertion of a logic high signal level at control input 112c, current source circuit 112 generates current ICHARGE to yet an even higher level to thereby cause voltages REF1 and VGATE to increase at even higher rates as shown at 210. Because the Vds of transistor M1 is fairly low (e.g., 2V) and decreasing as capacitor CLOAD continues to charge, the current IOUT can increase as shown at 211 without risk of overheating transistor M1.

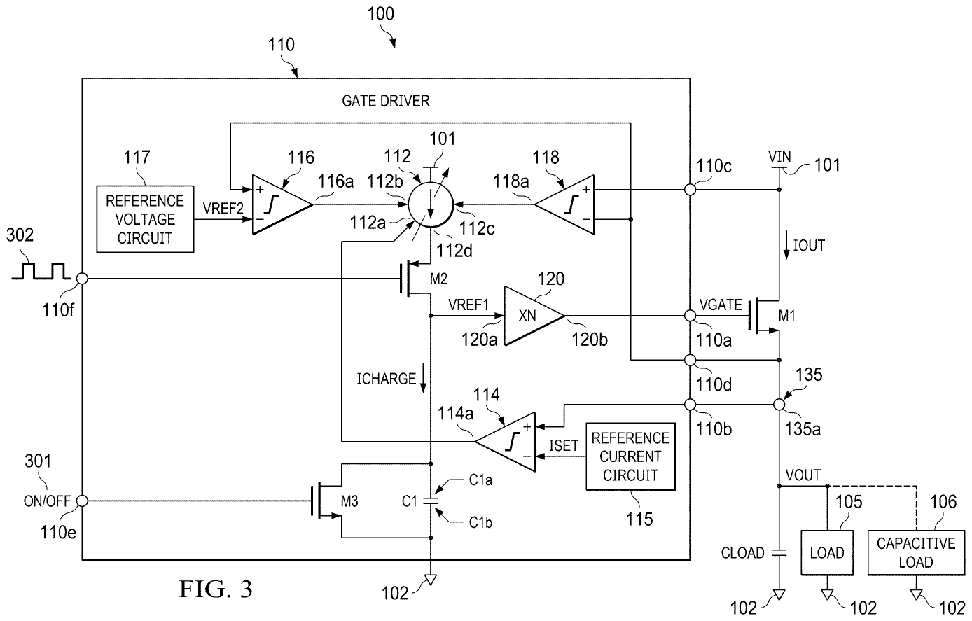

FIG. 3 is a schematic diagram of system 100 in another example in which gate driver 110 includes transistors M2 and M3. FIG. 3 illustrates a technique for how gate driver 110 can be activated to initiate the turn-on process for transistor M1 as described above. Transistor M3 is an n-channel field effect transistor (NFET) whose drain and source are coupled across capacitor C1. The gate of transistor M3 is coupled to a terminal 110e of gate driver 110 through which an ON/OFF signal 301 is provided. In this example, with the ON/OFF signal at a logic high level, transistor M3 is on thereby pulling voltage VREF1 low towards ground. With VREF1 at or near ground, VGATE is below the threshold voltage for transistor M1, and accordingly, transistor M1 is off. With the ON/OFF signal at a logic low level, transistor M3 is off and gate driver 110 is permitted to operate as described above.

Transistor M2 is coupled in series between output 112d of current source circuit 112 and terminal C1a of capacitor C1. The gate of transistor M2 is coupled to terminal 110f of gate driver 110. A clock signal 302 is provided to the gate of transistor M2 to turn transistor on and off. When transistor M2 is on, current ICHARGE flows through transistor M2 to charge capacitor C1. When transistor M2 is off, current ICHARGE does not flow through to capacitor C1. Accordingly, the average charge current for capacitor C1 in the example of FIG. 3 is ICHARGE*D, where D is the duty cycle of clock signal 302. For example, if D is 0.5, then the average charge current for capacitor C1 is ICHARGE/2. Accordingly, the various levels of the charge current to capacitor C1 as described above is ICHARGE*D. By duty-cycling transistor M2, current source circuit 112 can generate current ICHARGE at higher levels which allows for fine control over the current from current source circuit 112.

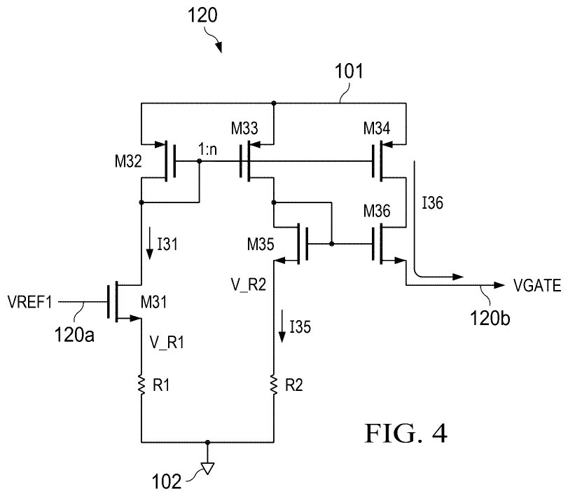

FIG. 4 is a circuit schematic of buffer 120, in an example. Buffer 120 includes transistors M31, M32, M33, M34, M35, and M36, and resistors R1 and R2. Transistors M31, M35, and M36 are NFETs, and transistors M32-M34 are p-channel field effect transistors (PFETs). The sources of transistors M32-M34 are coupled together and to a supply voltage terminal 401 (e.g., an internally-generated supply voltage). The gates of transistors M32-M34 are coupled together and to the drain of transistor M32. The drains of transistors M32 and M31 are coupled together. One terminal of resistor R1 is coupled to the source of transistor M31, and the other terminal of resistor R1 is coupled to the supply voltage terminal 102. The gate of transistor M31 is coupled to buffer input 120a and receives the voltage VREF1. The drain of transistor M33 is coupled to the drain of transistor M35 and to the gates of transistors M35 and M36. The drains of transistors M34 and M36 are coupled together. One terminal of resistor R2 is coupled to the source of transistor M35, and the other terminal of resistor R2 is coupled to the supply voltage terminal 102. The source of transistor M36 is coupled to the buffer output 120b and provides the voltage VGATE.

Current I31 is the current through transistors M31 and M32. Current I35 is the current through transistors M35 and M33. Current I36 is the current through transistors M36 and M34 and to the gate of transistor M1 (FIGS. 1 and 2). The combination of transistors M32 and M33 forms a current mirror. The current mirror ratio is 1: n meaning that current I35 is n-times as large as current I31. In one example, n is 3. Resistor R2 may have a resistance that is m-times larger than the resistance of resistor R1. In one example, m is 3 which means that the resistance of resistor R2 is 3-times as large as the resistance of resistor R1.

The voltage V_R1 at the source of transistor M31 is voltage VREF1 at its gate minus the threshold voltage transistor M31. Current I31 is voltage V_R1/R1. In the example in which the current mirror ratio between transistors M32 and M33 is 1:3, current I35 is 3*I31. Current I35, which is 3-times as large as current I31 flows through resistor R2, which has 3-times the resistance as resistor R1. Accordingly, with an example current mirror ratio of 1:3 and R2 being 3*R1, the voltage V_R2 across resistor R2 is 9-times the voltage V_R1. The voltage at the gates of transistors M35 and M36 is the threshold voltage of transistor M35 above voltage V_R2, and the voltage at the source of transistor M36 is a threshold voltage below the voltage at the gate of transistor M36. Accordingly, voltage VGATE is approximately equal to voltage V_R2. Because voltage V_R2 is n*m*V_R1 and V_R1 is proportional to (e.g., a threshold voltage less than) voltage VREF1, voltage VGATE also is n*m*VREF1 and is proportional to voltage VREF1. In the example described above in which n and m are both 3, voltage VGATE is approximately 9-times VREF1 (ignoring the threshold voltage of transistor M31). Accordingly, buffer 120 implements a gain of n*m, which is a gain of 9 when n=m=3. In some examples, the gain of buffer 120 is between 8 and 11. Transistor M34 supplies the current to the gate of transistor M1 that is needed to maintain voltage VGATE at approximately n*m*VREF1.

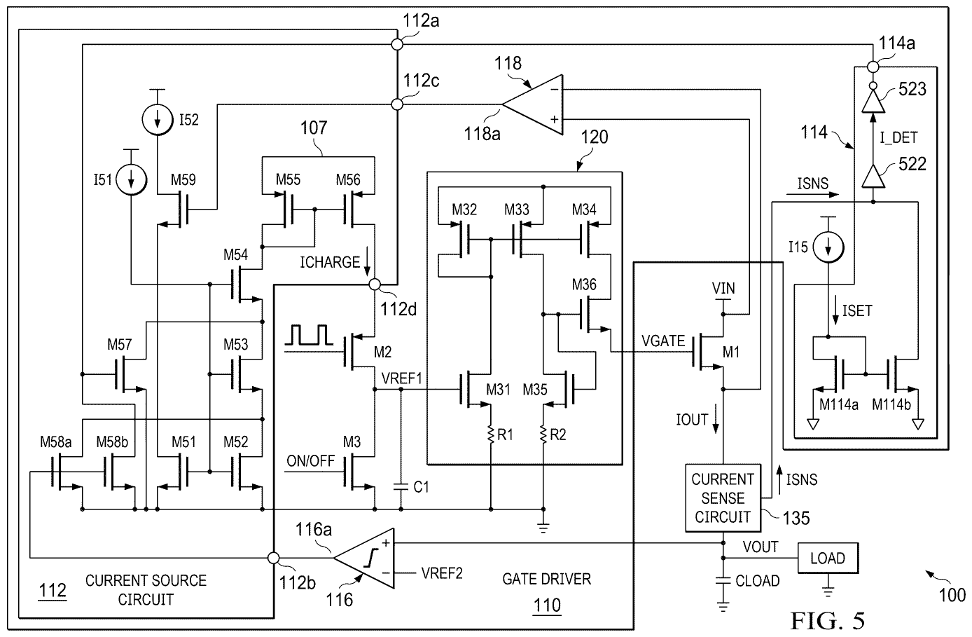

FIG. 5 is a schematic diagram of system 100 providing example implementations of current source circuit 112 and comparator 114. Comparator 114 includes transistors (e.g., NFETs) M114a and M114b, a Schmitt trigger 522, and an inverter 523. Transistors M114a and M114b are coupled together to form a current mirror. Reference current circuit 115 is coupled to transistor M114a and provides current ISET to through transistor M114a. Current ISET is mirrored through transistor M114b. In the example of FIG. 5 sense signal SNS is a current ISNS from current sense circuit 135. The input of Schmitt trigger 522 is coupled to the drain of transistor M114b and to the output of current sense circuit 135. If current ISNS is larger than the current through transistor M114b, then Schmitt trigger 522 generates a logic high at its output to the input of inverter 523. Otherwise, if current ISNS is smaller than the current through transistor M114b, then Schmitt trigger 522 generates a logic low at its output to the input of inverter 523. The output of inverter 523 is coupled to the gate of transistor M57 and the drain of transistor M58b, described below.

Current source circuit 112 includes transistors M51, M52, M53, M54, M55, M56, M57, M58a, M58b, and M59, and current sources I51 and I52. In this example, transistors M55, M56, and M59 are PFETs, and transistors M51-M54 and M57, M58a, and M58b are NFETs. Transistors M52, M53, M54, and M55 are coupled in series between an internal supply terminal 107 and ground. Transistors M55 and M56 are coupled together forming a current mirror. The drain of transistor M56 is coupled to output 112d of current source circuit 112. The current through transistor M56 is current ICHARGE, which charges capacitor C1 when transistor M3 is off.

The drain of transistor M59 is coupled to current source I52 and the source of transistor M59 is coupled to current source I51 and to the drain of transistor M51. The gates of transistors M51, M52, M53, and M54 are coupled together and to the source of transistor M59 and the drain of transistor M51. The gates of transistors M58a and M58b are coupled together and to the output 116a of comparator 116. The sources of transistor M58a, M58b, M51, and M52 are coupled together and to ground. The drain of transistor M58a is coupled to the drain of transistor M52 and to the source of transistor M53. The drain of transistor M58b is coupled to the gate of transistor M57 and to the output of inverter 523. When the output signal form inverter 523 is logic high, transistor M57 turns on. When the output signal from comparator 116 is logic high, transistors M58a and M58b turn on. Further, the output 118a of comparator 118 is coupled to the gate of transistor M59. Accordingly, when the output signal from comparator 118 is logic high, transistor M59 turns on.

Current from current source I51 flows through transistor M51. Similarly, when transistor M59 is on, current from current source I52 also flows through transistor M51. Accordingly, when transistor M59 is on, current from both current sources I51 and I52 flows through transistor M51. Upon initiating the process of turning on transistor M1, transistors M58a, M58b, and M59 are off. With current IOUT, via its proxy ISNS, being less than ISET, the output of Schmitt trigger 522 is logic low and the output of inverter 523 is logic high thereby turning on transistor M57. In this configuration, a current mirror is formed between transistor M51 and transistor M54, and, accordingly, current from current source I51 flowing through transistor M51 is mirrored through transistor M54 (e.g., 1:1 current mirror ratio). Current ICHARGE is approximately equal to the current from current source I51. Current ICHARGE in this configuration (transistor M57 on) represents the charge current for capacitor C1 in the phase RAMP1 (FIG. 2).

When current IOUT, via its proxy ISNS, reaches ISET (during the phase RAMP2), the output of Schmitt trigger 522 trips to a logic high state which inverter 523 inverts to a logic low state thereby turning off transistor M57. With transistor M57 off, a current mirror is formed between transistor M51 and the series combination of transistors M52-M54. The current mirror ratio in this configuration is 3:1 because the series combination of transistors M52-M54 is equivalent to a transistor having a channel length L that is 3-times the channel length of transistor M51, assuming all individual transistors in this example have the same channel width W and channel length L. Accordingly, current ICHARGE decreases during the periods of time identified in FIG. 2 as 204 and 205. During phase RAMP2, current ICHARGE changes between two levels—one level equal to current from current source I51 and another level equal to one-third the magnitude of the current from current source I51.

When current IOUT, via its proxy ISNS, falls to the lower level 202 in FIG. 2, the output of Schmitt trigger 522 changes to a logic low state which inverter 523 inverts to a logic high state thereby again turning on transistor M57. As a result, current ICHARGE increases during the period of time 206, as described above.

Comparator 116 determines when the output voltage VOUT reaches reference voltage VREF2, which marks the end of phase RAMP2 and beginning of phase RAMP3. When VOUT reaches VREF2, comparator 116 forces its output 116a to a logic high state, which causes transistors M58a and M58b to turn on. Turning on transistor M58b forces transistor M57 to remain off for the remainder of the turn-on process for transistor M1. Turning on transistor M58a causes a reconfiguration of the current mirror to be a current mirror between transistor M51 and the series-combination of transistors M53 and M54, which has a current mirror ratio of 2:1. In this configuration (transistor M58a on), current ICHARGE is less than current ICHARGE was during the phase RAMP1 and larger than ICHARGE was during the phase RAMP2 when transistor M57 was off.

Finally, when comparator 118 determines that voltage VOUT is within the threshold voltage of comparator 118 of voltage VIN, comparator 118 forces its output 118a to a logic high state thereby turning on transistor M59. With transistor M59 on, current from current source I52 is added to the current from current source I51 that flows through transistor M51, and current ICHARGE increases to an even higher level, which occurs during time period 210 in FIG. 2.

In some examples, the rate of change of voltage VGATE during the phases RAMP1, RAMP2, and RAMP3 can be configured. For example, gate driver 110 may include one or more registers into which values can be programmed via, for example, an interface (e.g., an Inter-Integrated Circuit bus, a Serial Peripheral Interface bus, etc.). In some such examples, the rate of changes of voltage VGATE can be configured by configuring the magnitude of the currents produced by current source circuit 112. In a specific example, a configuration value can be programmed into gate driver 112 that adjusts the current ICHARGE produced by current source circuit 112 during all of the phases RAMP1-RAMP3 proportionally.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input is the gate, and the current terminals are the drain and source. In the context of a BJT, the control input is the base, and the current terminals are the collector and emitter.

References herein to a FET being “ON” or “enabled” means that the conduction channel of the FET is present and drain current may flow through the FET. References herein to a FET being “OFF” or “disabled” means that the conduction channel is not present so drain current does not flow through the FET. An “OFF” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described examples, and other examples are possible, within the scope of the claims.

What is claimed is:

1. An apparatus, comprising:
a current source circuit having a first control input, a second control input, and an output, the current source circuit configured to produce a current at the output at a first current level based on a first signal at the first control input being at a first logic level and at a second current level based on the first signal at the first control input being at a second logic level, and the current source circuit is configured to produce the current at the output at a third current level based on a second signal at the second control input;
a capacitor having a first terminal coupled to the output of the current source circuit and having a second terminal coupled to a voltage supply terminal; and
a buffer having a buffer input coupled to the first terminal and having a buffer output.

2. The apparatus of claim 1, further comprising a transistor having a control terminal coupled to the buffer output.

3. The apparatus of claim 2, further comprising:
a current sense circuit coupled to the transistor, the current sense circuit having a sense output; and
a current comparator having a first comparator input, a second comparator input, and a comparator output, the first comparator input coupled to the sense output, the second comparator input coupled to a reference current circuit, and the comparator output coupled to the first control input.

4. The apparatus of claim 2, wherein the transistor has a transistor terminal, and the apparatus further comprises a comparator having a first comparator input, a second comparator input, and a comparator output, the first comparator input coupled to the transistor terminal, the second comparator input coupled to a reference voltage circuit, and the comparator output coupled to the second control input.

5. The apparatus of claim 2, wherein the transistor has a first transistor terminal and a second transistor terminal, and the current source circuit has a third control input, the current source circuit is configured to produce the current at the output at a fourth current level based on a third signal at the third control input, and the apparatus further comprises:
a comparator having a first comparator input, a second comparator input, and a comparator output, the first comparator input coupled to the first transistor terminal, the second comparator input coupled to the second transistor terminal, and the comparator output coupled to the third control input.

6. The apparatus of claim 1, further comprising a transistor coupled between the output of the current source circuit and the first terminal of the capacitor.

7. An apparatus, comprising:
a transistor having a control terminal; and
a driver including a configurable current source circuit, the configurable current source circuit having control inputs, the driver having a driver output coupled to the control terminal, the driver configured to generate a voltage at the control terminal that changes at multiple rates based on control signals at the control inputs of the configurable current source circuit.

8. The apparatus of claim 7, further comprising:
a current sense circuit coupled to the transistor, the current sense circuit having a sense output; and
a comparator having a first comparator input coupled to the sense output, the comparator having a comparator output coupled to a first control input of the configurable current source circuit's control inputs, the comparator configured to compare a signal at the sense output to a reference current; and
wherein the driver is configured to generate the voltage at the control terminal at a first rate of the multiple rates based on a signal at the comparator output being at a first logic state and to produce the voltage at the control terminal at a second rate of the multiple rates based on the signal at the comparator output being at a second logic state.

9. The apparatus of claim 8, wherein the comparator is a first comparator, the transistor has a transistor terminal, and the apparatus further comprises:
a second comparator having a first comparator input coupled to the transistor terminal, the second comparator having an output coupled to a second control input of the current source circuit's control inputs, the second comparator configured to compare a voltage at the transistor terminal to a reference voltage; and
wherein the driver is configured to generate the voltage at the control terminal at a third rate of the multiple rates based on a signal at the output of the second comparator.

10. The apparatus of claim 9, wherein the first comparator is a current comparator, and the second comparator is a voltage comparator.

11. The apparatus of claim 7, wherein the driver includes a capacitor having a capacitor terminal coupled to an output of the configurable current source circuit.

12. The apparatus of claim 11, further comprising a buffer having a buffer input coupled to the capacitor terminal and having a buffer output coupled to the driver output.

13. The apparatus of claim 12, wherein the buffer has a gain, and the gain is greater than 1.

14. The apparatus of claim 13, wherein the gain is between 8 and 11.

15. The apparatus of claim 12, wherein the transistor is a first transistor, the driver further includes a second transistor coupled between output of the configurable current source circuit and the capacitor terminal.

16. The apparatus of claim 7, wherein the transistor has a transistor terminal, and wherein the driver is configured to:
generate the voltage at the control terminal at first rate and second rates of the multiple rates until a voltage at the transistor terminal reaches a threshold voltage; and
generate the voltage at the control terminal at a third rate of the multiple rates when the voltage at the transistor terminal is above the threshold voltage.

17. A driver, comprising:
a current source circuit having a first control input, a second control input, and an output;
a capacitor having a first terminal coupled to the output of the current source circuit and having a second terminal coupled to a voltage supply terminal;
a buffer having a buffer input coupled to the first terminal and having a buffer output;
a first comparator having first and second comparator inputs and an output, the first comparator input coupled to a first terminal of the driver, the second comparator input configured to receive a first reference signal, the output of the first comparator coupled to the first control input of the current source circuit; and
a second comparator having third and fourth comparator inputs and an output, the third comparator input coupled to a second terminal of the driver, the fourth comparator input configured to receive a second reference signal, the output of the second comparator coupled to the second control input of the current source circuit.

18. The driver of claim 17, wherein the current source circuit is configured to provide a current at first, second, and third current levels based on signals from the outputs of the first and second comparators.

19. The driver of claim 17, wherein the first comparator is a current comparator, and the second comparator is a voltage comparator.

20. The driver of claim 17, wherein the current source circuit has a third control input, and the driver further comprises:
a third comparator having a fifth and sixth comparator inputs and an output, the fifth comparator input coupled to the second terminal of the driver, the sixth comparator input coupled to a fourth terminal of the driver, the output of the third comparator coupled to the third control input of the current source circuit.
